(19) United States
(12) Patent Application Publication
(10) Pub. No.: US 2007/0249112 A1
(43) Pub. Date: Oct. 25, 2007

(54) DIFFERENTIAL SPACER FORMATION FOR A FIELD EFFECT TRANSISTOR

(75) Inventors: Brian Joseph Geene, Yorktown Heights, NY (US); Dan Mihai Mocuta, Lagrangeville, NY (US); Gaku Sudo, Yokohama-shi (JP)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignees: INTERNATIONAL BUSINESS MACHINES CORPORATION, Armonk, NY (US); TOSHIBA CORPORATION SEMICONDUCTOR COMPANY, Tokyo (JP)

(21) Appl. No.: 11/308,686

(22) Filed: Apr. 21, 2006

(51) Int. Cl. H01L 21/8238

(52) U.S. Cl. 438/199; 438/230; 438/233

(57) ABSTRACT

A method for manufacturing an integrated circuit includes providing one or more n-type field effect transistor and one or more p-type field effect transistor on a semiconductor substrate. Each of the transistors separated by a trench isolation structure. Each of the transistors has a source and drain regions formed in the semiconductor layer and a gate electrode formed above the semiconductor layer. An oxide liner is deposited across the upper surface of the integrated circuit and onto each of the one or more n-type field effect transistors and one or more p-type field effect transistors. A nitride liner depositing is deposited the oxide liner. At least a portion of the nitride liner on each of the one or more p-type field effect transistor is removed to form nitride sidewall spacers. Additional source and drain regions are implanted into the one or more p-type field effect transistors. The integrated circuit is annealed. The nitride liner is removed from the one or more n-type field effect transistors. The exposed oxide liner is removed from the semiconductor substrate and the one or more n-type field effect transistors and the one or more p-type field effect transistors whereby each of the one or more p-type field effect transistor has greater silicide proximity than each of the one or more n-type field effect transistors, thereby allowing increased performance of each of the one or more p-type field effect transistors without adversely affecting performance of each of the one or more n-type field effect transistors.

### FIELD OF THE INVENTION

The present invention relates to the manufacturing of integrated circuits. More particularly, the present invention relates to the formation of spacer elements during the manufacturing of semiconductor devices comprised of one or more field effect transistors.

### BACKGROUND OF THE INVENTION

During the fabrication of complex integrated circuits, many n-type transistors and p-type transistors are formed on a substrate including a crystalline semiconductor layer. A field effect transistor comprises device junctions (so-called PN junctions) that are formed by an interface of doped drain and source regions with an inversely doped channel region between the drain region and the source regions.

When an appropriate control voltage is applied to the gate electrode, the channel region becomes conductive. The conductivity of the channel region depends on the dopant concentration, the mobility of the majority charge carriers, as well as the distance between the source and drain regions, which is also referred to as channel length.

Sophisticated spacer techniques are necessary to create the highly complex dopant profile and to serve as a mask in forming metal silicide regions in the gate electrode and the drain and source regions in a self-aligned fashion. Spacers are commonly employed to physically offset the shallow junctions in the source and drain extension regions from the considerably deeper junctions employed in the source and drain regions of the transistor.

Multiple spacers, formed successively, enable additional flexibility in device design and performance optimization by enabling more complex source and drain junction profiles, the use of additional implant species, and independent control of silicide proximity to the transistor channel, for example. However, the additional complexity of a multiple-spacer process flow can be reasonably expected to increase manufacturing costs and cycle times, and lower process yield.

Therefore, what is needed is a technique that reduces the complexity of the multiple-spacer technique, while maintaining flexibility in device junction design.

### SUMMARY OF THE INVENTION

The present invention discloses a method for manufacturing an integrated circuit comprising the steps of: providing a plurality of semiconductor devices including one or more n-type field effect transistor and one or more p-type field effect transistor on a semiconductor substrate, each of the transistors separated by a trench isolation structure, each of the transistors having source and drain regions formed in the semiconductor substrate and a gate electrode formed above the semiconductor substrate; depositing an oxide liner across the upper surface of the integrated circuit and onto each of the one or more n-type field effect transistors and one or more p-type field effect transistors; depositing a nitride liner over the oxide liner; removing at least a portion of the nitride liner on each of the one or more p-type field effect transistor to form nitride sidewall spacers; implanting additional source and drain regions into the one or more p-type field effect transistors; annealing the integrated circuit; removing the nitride liner from the one or more n-type field effect transistors; and removing exposed oxide liner from the semiconductor substrate and the one or more n-type field effect transistors and the one or more p-type field effect transistors; whereby each of the one or more p-type field effect transistor has greater silicide proximity than each of the one or more n-type field effect transistors, thereby allowing increased performance of each of the one or more p-type field effect transistors without adversely affecting performance of each of the one or more n-type field effect transistors.

According to the present invention, the step of removing at least a portion of the nitride liner on each the one or more p-type field effect transistor is performed by an anisotropic reactive ion etch.

Further according to the present invention, the step of depositing an oxide liner onto each of the one or more n-type field effect transistors and each of the one or more p-type field effect transistors comprises depositing an oxide liner with a thickness in the preferable range of about 2 nanometers to about 20 nanometers and more preferably in the range of about 5 nanometers to about 15 nanometers. The oxide liner is formed a material selected from the group consisting essentially of silicon oxide and silicon oxynitride. The oxide liner is deposited at a temperature preferably below about 600 ° C. and more preferably about 150° C. and about 500° C.

Also according to the present invention, the nitride liner has a thickness in the range of about 15 nanometers to about 100 nanometers and more preferably in the range of about 30 nanometers to about 60 nanometers. The deposited nitride liner is formed of silicon nitride.

According to the present invention, the step of removing at least a portion of the nitride liner from the one or more p-type field effect transistors includes completely removing the nitride liner from the top of the one or more p-type field effect transistors and forming a plurality of nitride sidewall spacers with a thickness in the range of about 10 nanometers to about 50 nanometers at the base of the plurality nitride sidewall spacers. The step of removing the nitride liner from the n-type field effect transistors is performed with an anisotropic reactive ion etch.

Further according to the present invention, the step of annealing the semiconductor substrate is performed at a temperature of between about 800° C. and about 1300° C.

Also according to the present invention, a first metal layer is deposited on an exposed surface of each of the gate electrodes and a second metal layer is deposited on an exposed surface of the semiconductor layer of the integrated circuit. The first and second metal layer is formed of a metal selected from the group consisting essentially of nickel, cobalt, and platinum.

Further according to the present invention, the silicide proximity of the n-type field effect transistor is the distance from the second metal layer on the exposed surface of the semiconductor layer of the integrated circuit adjacent the nitride sidewall spacer and the gate of the n-type field effect transistor. The silicide proximity of the p-type field effect transistor is the distance from the second metal layer on the exposed surface of the semiconductor layer of the integrated circuit adjacent the nitride sidewall spacer and the gate of the p-type field effect transistor. The silicide proximity of the n-type field effect transistor is from about 20 nanometers to about 50 nanometers and the silicide proximity of the p-type field effect transistor is from about 45 nanometers to about 100 nanometers. The silicide proximity of the n-type field effect transistor is greater than the silicide proximity of the p-type field effect transistor.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

In the drawings accompanying the description that follows, often both reference numerals and legends (labels, text descriptions) may be used to identify elements. If legends are provided, they are intended merely as an aid to the reader, and should not in any way be interpreted as limiting.

Often, similar elements may be referred to by similar numbers in various figures (FIGs) of the drawing, in which case typically the last two significant digits may be the same, the most significant digit being the number of the drawing figure (FIG).

FIGS. 1-8 schematically show cross-sectional views of an integrated circuit during the various steps of the method of the present invention; and

FIG. 9 is a flowchart indicating the sequence of steps of the method of the present invention.

### DETAILED DESCRIPTION OF THE INVENTION

Exemplary embodiments of the invention are described below. In the interest of clarity, not all features of an actual implementation are described in this specification. It will of course be appreciated that while the methods disclosed herein might be considered complex and time-consuming, they are able to be understood by those of ordinary skill in the art.

The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

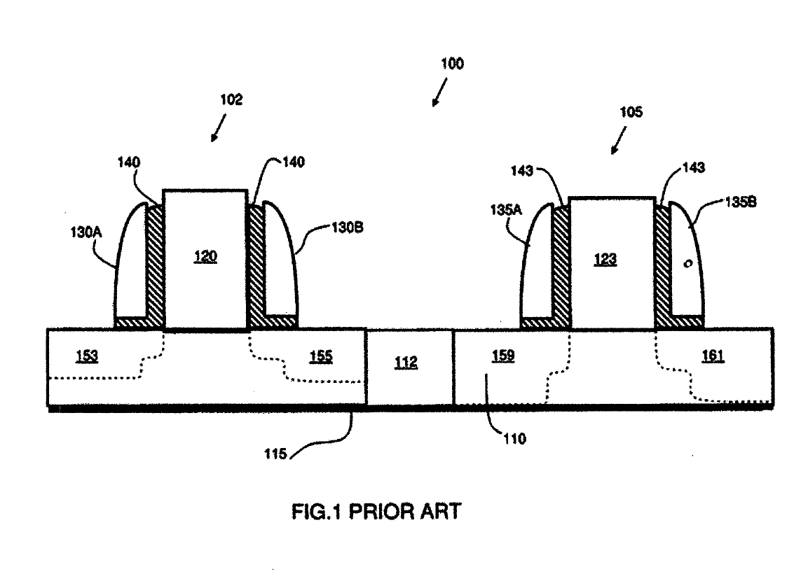

FIG. 1 shows a cross-sectional view of a prior art integrated circuit 100, prior to performing the steps of the present invention. For illustrative purposes, two types of field effect transistor are shown; PFET 102 and NFET 105. PFET 102 and NFET 105 each have been implanted, forming source and drain regions 153 and 155 of PFET 102, and source and drain regions 159 and 161 of NFET 105. As is known in the art, the source and drain regions are essentially identical. The integrated circuit 100 is comprised of substrate 115, which may represent any appropriate substrate for the formation of integrated circuits, such as a silicon substrate, a silicon-on-insulator (SOI) substrate, any other semiconductor substrate or insulating substrate having formed thereon a substantially crystalline semiconductor layer 110.

The individual transistors, whether PFET or NFET type, are separated by a trench isolation structure 112, typically formed from silicon oxide, which defines a transistor active region in the semiconductor layer 110. PFET 102 has source and drain regions 153, 155 formed on semiconductor layer 110. A gate electrode 120 is formed above the semiconductor layer 110 and is surrounded by a first oxide liner 140 and by offset sidewall spacers 130A, 130B. NFET 105 has source and drain regions 159, 161 formed on semiconductor layer 110. A gate electrode 123 is formed above the semiconductor layer 110 and is surrounded by a first oxide liner 143 and by offset sidewall spacers 135A, 135B.

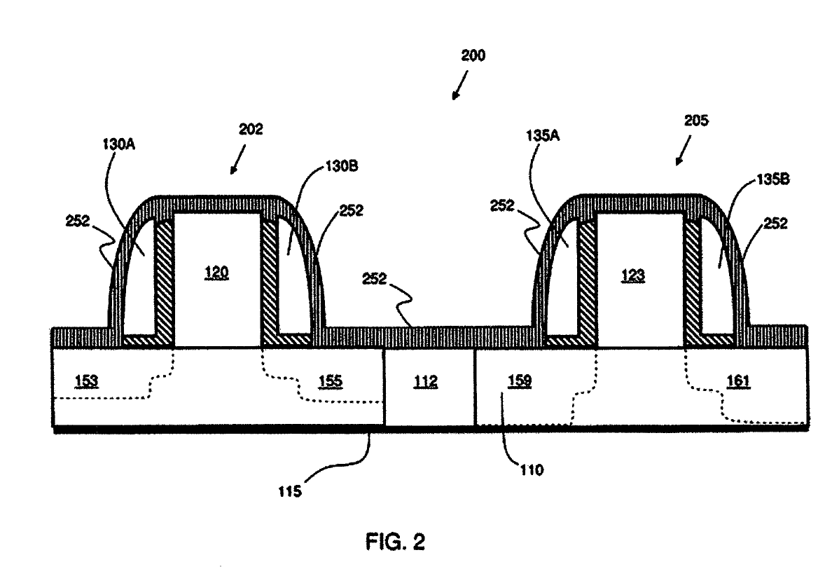

FIG. 2 shows a cross-sectional view of an integrated circuit 200 (incorporating the integrated circuit 100 in FIG. 1), after performing the first step of the present invention. This first step comprises the application of a Stress Memory Technique (SMT) oxide liner 252 across the upper surface of the integrated circuit 200. The Stress Memory Technique (SMT) oxide liner 252 is formed from the group of materials consisting essentially of silicon oxide and silicon oxynitride. The thickness of the SMT oxide liner 252 is from 2 nanometers to about 20 nanometers. Preferably, the thickness of the SMT oxide liner 252 is from 5 nanometers to about 15 nanometers. If the thickness of the SMT oxide liner 252 is greater than 20 nanometers, then in general, no additional benefit is achieved. If the thickness of the SMT oxide liner 252 is less than 2 nanometers, then the oxide liner 252 is too thin to have sufficient insulating properties. Typically, the SMT oxide liner 252 would be deposited by chemical vapor deposition or plasma deposition techniques at low temperatures to avoid unnecessary dopant diffusion. Temperatures of below about 600° Centigrade (C.) and preferably between about 150° C. and 500° C. and most preferably between 300° C. and 400° C. are typically sufficient for the deposition techniques. Depositing the SMT oxide liner 252 at a temperature of below about 150° C. would not work because the temperature would be too low for the deposition process to occur. The SMT oxide liner 252 serves as a protective layer for the integrated circuit 200 during the manufacturing process.

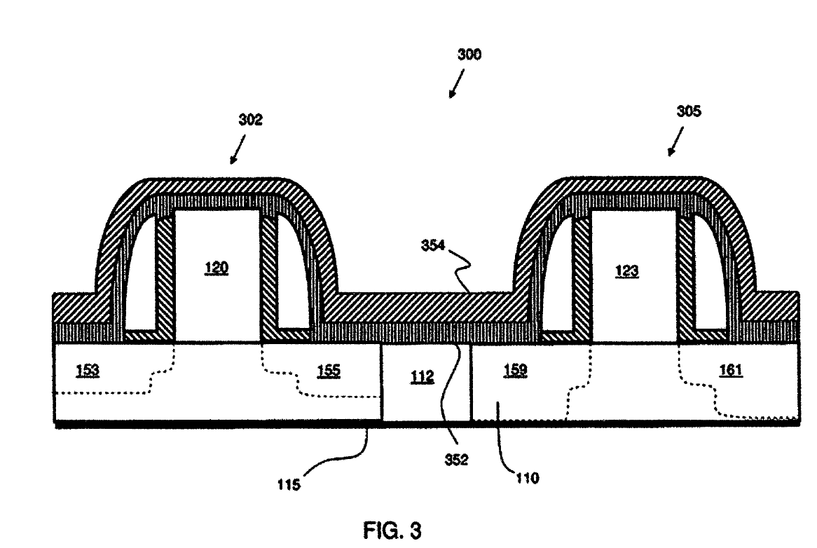

FIG. 3 shows a cross-sectional view of an integrated circuit 300 (incorporating the integrated circuit 200 of FIG. 2), after depositing a SMT nitride liner 354 over SMT oxide liner 352 (compare oxide layer 252 in Figure), which has previously been applied to the integrated circuit 300. The SMT nitride liner 354 is formed from silicon nitride. The SMT nitride liner 354 is used to form additional spacing on the PFET device 302 as will be illustrated in upcoming figures. In each figure, reference numbers x02 and x05 are generally similar, with the possible addition or removal of some material. For example, PFET device 302 of FIG. 3 is the same device as PFET device 202 of FIG. 2, with the addition of material, namely, SMT nitride liner 354. The additional spacing from the SMT nitride liner 354 enables a more desirable silicide proximity for PFET devices. The thickness of the SMT nitride liner 354 is from 15 nanometers to about 100 nanometers. More preferably, the thickness of the SMT nitride liner 354 is from 30 nanometers to about 60 nanometers. If the thickness of the SMT nitride liner 354 is greater than 100 nanometers, then no additional benefit is achieved. If the thickness of the SMT nitride liner 354 is less than 15 nanometers, then adequate protection is not provided. Typically, the SMT nitride liner 354 would be deposited by vapor deposition techniques.

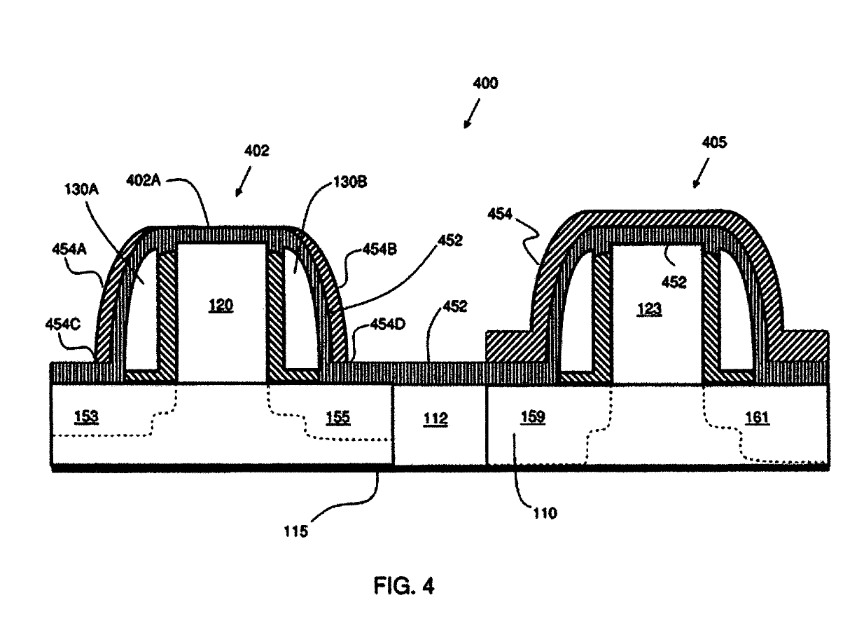

FIG. 4 shows a cross-sectional view of an integrated circuit 400 (incorporating the integrated circuit 300 in FIG. 3), after removing a portion of the SMT nitride liner 454 (compare nitride liner 354 in FIG. 3) from the top portion of PFET device 402 (compare PFET device 302). Using lithographic methods, the SMT nitride liner 454 is preserved on the NFET device 405. The SMT nitride liner 454 is removed from the top 402A, from the left side above the SMT oxide liner 452 (compare oxide liner 352 of FIG. 3) and from the right side above the SMT oxide liner 452 extending to the SMT nitride liner 454 of the NFET device 405. Note that only the side portions 454A, 454B (differential sidewall spacers) remain. The technique used to remove SMT nitride liner 454 from PFET 402 is preferably an anisotropic reactive ion etch (RIE) because RIE achieves anisotropic profiles, and enables fast etch rates and a high level of dimensional control. The sidewall spacers 454A and 454B are additional to spacers 130A and 130B (FIG. 1) so as to enhance the performance of the PFET device 402. Sidewall spacers 454A and 454B each have a base 454C and 454D, respectively, where they contact SMT oxide liner 452. Each of these side portions 454A, 454B become thinner as they approach the top 402A. Sidewall spacers 454A and 454B are preferably 10 to 50 nanometers wide at the base 454C and 454D, respectively. If the sidewall spacers 454A and 454B are greater than 50 nanometers wide then a desirable suicide proximity for PFET device 402 would not be achieved. If the sidewall spacers 454A and 454B are less than 10 nanometers wide than their effects would be negligible, and similarly, a desirable silicide proximity for PFET device 402 would not be achieved.

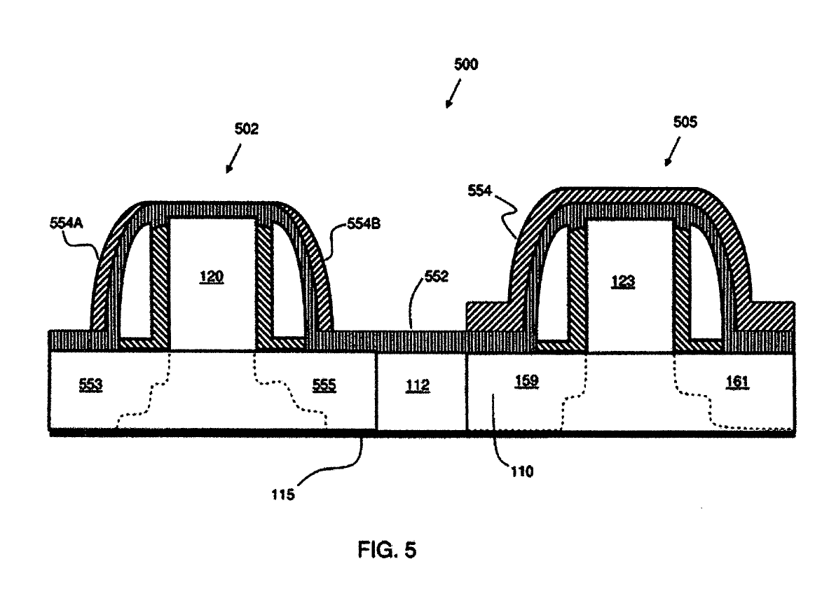

FIG. 5 shows a cross-sectional view of an integrated circuit 500 (incorporating the integrated circuit 400 in FIG. 4) after additional implanting of the source and drain regions 553 and 555 of PFET 502 which were initially implanted prior to initiating the steps of the present invention. The source and drain regions of NFET 505, indicated as 159 and 161 were implanted prior to beginning the method of the present invention, and are essentially identical to references 159 and 161, respectively, of FIG. 1. The additional implanting of the source and drain regions 553 and 555 is controlled by the sidewall spacers 554A and 554B (compare sidewall spacers 454A and 454B of FIG. 4) which are formed upon the SMT nitride liner 552. When PFET 505 is implanted from above, the implant species (typically Boron or Indium) passes through oxide liner 552, but cannot pass through the SMT nitride liner that forms the spacers, indicated as 554A and 554B. The speed of diffusion of the PFET implant species requires that the additionally implanted areas of the source and drain regions 553 and 555 be placed farther away from the gate 120 of PFET device 502 than would be the case with NFET device 505.

The next step in the method of the present invention is to perform a high temperature activation anneal on the integrated circuit 500. The temperature of the high temperature activation anneal is between about 800° C. and 1300° C. and preferably between about 1000° C. and 1100° C. If the temperature of the activation anneal is above 1200° C. then, no additional benefit is gained. If the temperature of the activation anneal is below 800° C. then, the dopants will not diffuse sufficiently. The activation anneal causes dopants in the semiconductor layer 110 to diffuse, and the semiconductor material of the integrated circuit 500 to re-crystallize. The present invention can be practiced with a variety of anneal techniques, including, but not limited to, rapid thermal anneal, flash anneal, and laser anneal.

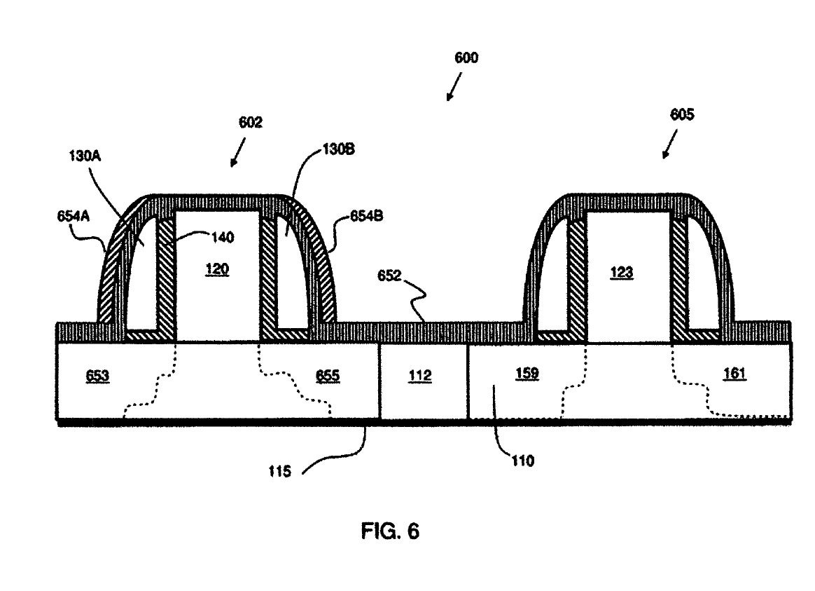

FIG. 6 shows a cross-sectional view of an integrated circuit 600 (incorporating the integrated circuit 500 of FIG. 5), after removing the SMT nitride liner 554 from the entire NFET device 605 (compare device 505 in FIG. 5). An etch technique is preferably used to remove the SMT nitride liner 554 from NFET device 605, without removing the SMT oxide liner 652 (compare 552 of FIG. 5). Lithographic techniques are used to protect sidewall spacers 654A and 654B of PFET device 602 during the etching.

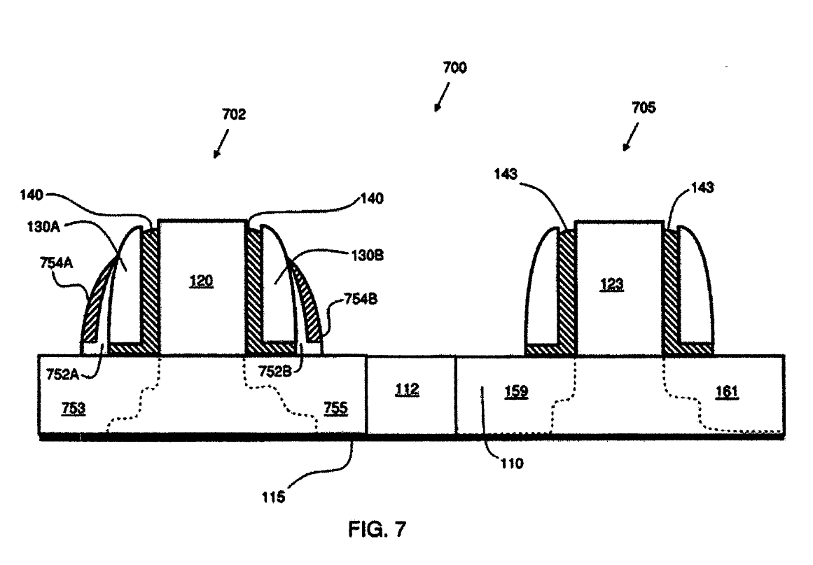

FIG. 7 shows a cross-sectional view of an integrated circuit 700 (incorporating the integrated circuit 600 of FIG. 6), after removing the majority of the SMT oxide liner 752 (compare liner 652 of FIG. 6). The removal of the majority of the SMT oxide liner 752 is preferably done using a conventional wet etch technique. At this stage of the process, only portions 752A and 752B of the SMT oxide liner 752, generally between the sidewall spacers 130 and the portion of SMT nitride liner indicated as 754A and 754B, respectively, remain. The result of the aforementioned steps creates a different silicide proximity for NFET device 705 than for PFET device 702. The silicide proximity is the distance between the implanted source and drain regions 753, 755 and the gate electrode 120 of the device 702.

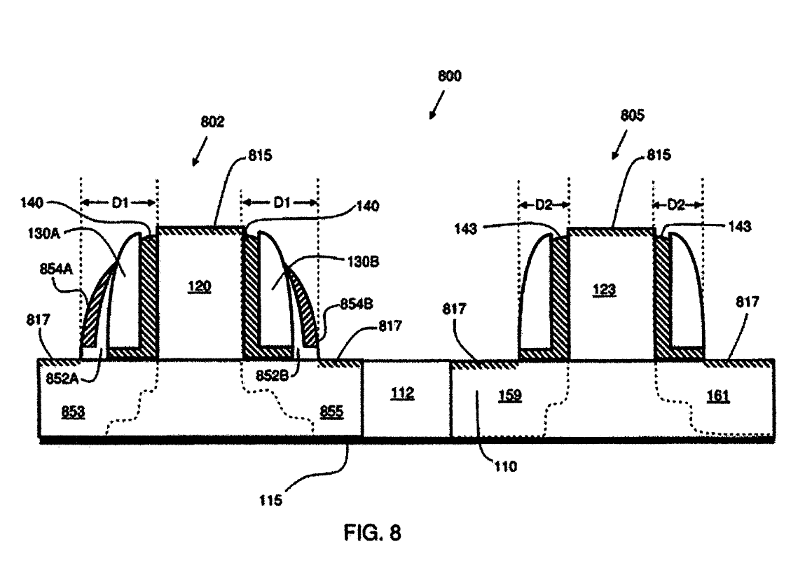

FIG. 8 shows a cross-sectional view of an integrated circuit 800 (incorporating the integrated circuit 700 of FIG. 7), after depositing a metal layer 815 which reacts with exposed silicon of the gate electrodes 120, 123 and metal layer 817 which reacts with exposed silicon of the silicon circuit 110, respectively. A variety of metals are suitable for the deposited material 815, 817 of the gate electrodes 120, 123, and the silicon circuit 110, respectively. Typically metal layers 815 and 817 are formed of Nickel, Cobalt, or Platinum. The deposited metal material 815 and 817 only reacts with the exposed silicon, but not with the oxide layer 852A, 852B or the nitride layer 854A, 854B. By depositing the metal layer 817, the semiconductor resistance is reduced, which is generally desirable in a semiconductor device. The silicide proximity of the PFET device 802 is indicated by distance D1, and the silicide proximity of the NFET device 805 is indicated by distance D2. Distances D1 and D2 represent the distance between the metal layer 817 of the final deposition, and the gate of the device (120 for PFET 802, and 123 for NFET 805). Distance Dl of the PFET device 802 is about 45 nanometers to about 100 nanometers. Distance D2 of the NFET device 805 is about 20 nanometers to about 50 nanometers. Distance D1 is preferably greater than distance D2. The NFET device 805 has silicide proximity less than that the PFET device 802. This corresponds to inherent properties of these devices, allowing satisfactory performance from both NFET device 805 and PFET device 802 on integrated circuit 800.

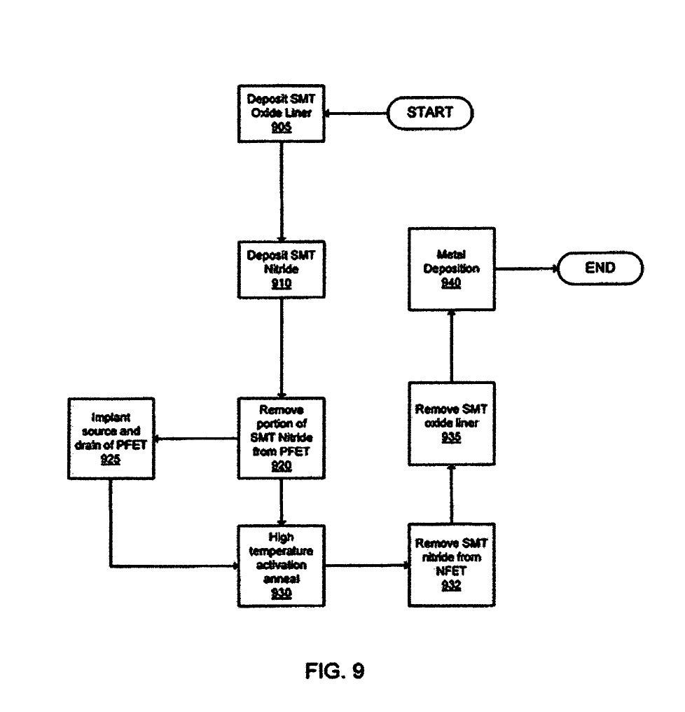

FIG. 9 is a flowchart indicating the sequence of steps of the method of the present invention. First (see FIG. 2), in step 905, an SMT oxide liner 252 is deposited onto an integrated circuit 110 comprising one or more PFET and NFET devices, 202 and 205, respectively. Next, in step 910 (see FIG. 3), an SMT nitride liner 354 is deposited over the SMT oxide liner 352. Continuing (see FIG. 4), in step 920, a portion of the SMT nitride liner 454 is removed from the PFET device 402. More specifically, a removal technique, such as anisotropic reactive ion etch (RIE) is used to remove the SMT nitride liner 454 from the PFET 402 everywhere except for the sides of the gate electrode area. The portions of the SMT nitride liner 454 that remain form additional sidewall spacers 454A and 454B. Lithographic techniques are used to mask the NFET devices, so that the SMT nitride liner remains on the NFET devices.

The next Step 925 (see FIG. 5) is optional in the process. This step comprises implanting the source and drain areas 553, 555 of the PFET device 502, thereby improving PFET performance. In the following step 930 (see FIG. 6), the integrated circuit 600 undergoes a high temperature activation anneal. This causes dopants to diffuse, and the semiconductor material 110 to re-crystallize. In next step 932 (see FIG. 7), the SMT nitride liner 754 is removed from the NFET 605. In step 935, the SMT oxide liner 252 is removed from circuit 700 except for portions 752A, 752B between nitride liner 754A, 754B and offset sidewall spacers 130A, 130B. Finally, in step 940 (see FIG. 8), metal layer 815 is deposited on gate electrodes 120, 123, and metal layer 817 is deposited on the silicon circuit 110. A conventional manufacturing process is then used to complete the manufacture of the integrated circuit.

As can be seen from the preceding description, the present invention provides an improved method for manufacturing integrated circuits. The complexity of the manufacturing process is reduced, and reduced complexity often allows higher yield, with less defective parts during manufacture. It will be understood that the present invention may have various other embodiments. Furthermore, while the form of the invention herein shown and described constitutes a preferred embodiment of the invention, it is not intended to illustrate all possible forms thereof. It will also be understood that the words used are words of description rather than limitation, and that various changes may be made without departing from the spirit and scope of the invention disclosed. Thus, the scope of the invention should be determined by the appended claims and their legal equivalents, rather than solely by the examples given.

What is claimed is:

1. A method for manufacturing an integrated circuit comprising the steps of: providing a plurality of semiconductor devices including one or more n-type field effect transistor and one or more p-type field effect transistor on a semiconductor substrate, each of said transistors separated by a trench isolation structure, each of said transistors having source and drain regions formed in the semiconductor substrate and a gate electrode formed above the semiconductor substrate; depositing an oxide liner across the upper surface of said integrated circuit and onto each of said one or more n-type field effect transistors and one or more p-type field effect transistors; depositing a nitride liner over said oxide liner; removing at least a portion of said nitride liner on each of said one or more p-type field effect transistor to form nitride sidewall spacers; implanting additional source and drain regions into said one or more p-type field effect transistors; annealing said integrated circuit; removing said nitride liner from said one or more n-type field effect transistors; and removing exposed oxide liner from said semiconductor substrate and said one or more n-type field effect transistors and said one or more p-type field effect transistors; whereby each said one or more p-type field effect transistors has greater silicide proximity than each of said one or more n-type field effect transistors, thereby allowing increased performance of each said one or more p-type field effect transistors without adversely affecting performance of each of said one or more n-type field effect transistors.

2. The method of claim 1, wherein the step of removing at least a portion of said nitride liner on each of said one or more p-type field effect transistors is performed by an anisotropic reactive ion etch.

3. The method of claim 1, wherein the step of depositing an oxide liner onto each of said one or more n-type field effect transistors and each of said one or more p-type field effect transistors comprises depositing an oxide liner with a thickness in the range of about 2 nanometers to about 20 nanometers.

4. The method of claim 3, wherein the step of depositing an oxide liner comprises the step of depositing an oxide liner with a thickness in the range of about 5 nanometers to about 15 nanometers.

5. The method of claim 3, wherein the step of depositing an oxide liner comprises the step of depositing an oxide liner formed a material selected from the group consisting essentially of silicon oxide and silicon oxynitride.

6. The method of claim 3, wherein the step of depositing an oxide liner onto each of said one or more n-type field effect transistor and each of said one or more p-type field effect transistor comprises depositing the oxide liner at a temperature below about 600° C.

7. The method of claim 6, wherein the step of depositing an oxide liner onto each of said one or more n-type field effect transistor and each of said one or more p-type field effect transistor comprises depositing the oxide liner at a temperature between about 150° C. and about 500° C.

8. The method of claim 3, wherein the step of depositing a nitride liner over said oxide liner comprises depositing a nitride liner with a thickness in the range of about 15 nanometers to about 100 nanometers.

9. The method of claim 8, wherein the step of depositing a nitride liner over said oxide liner comprises depositing a nitride liner with a thickness in the range of about 30 nanometers to about 60 nanometers.

10. The method of claim 9, wherein the step of depositing a nitride liner comprises the step of depositing a nitride liner formed of silicon nitride.

11. The method of claim 1, wherein the step of removing at least a portion of said nitride liner from said one or more p-type field effect transistors includes completely removing the nitride liner from the top of said one or more p-type field effect transistors and forming a plurality of nitride sidewall spacers with a thickness in the range of about 10 nanometers to about 50 nanometers at the base of the plurality nitride sidewall spacers.

12. The method of claim 11, wherein the step of removing said nitride liner from said p-type field effect transistors is performed with an isotropic reactive ion etch.

13. The method of claim 1, wherein the step of annealing said semiconductor substrate is performed at a temperature of between about 800° C. and about 1300° C.

14. The method of claim 11, including the step of depositing a first metal layer on an exposed surface of each of the gate electrodes.

15. The method of claim 14, including the step of depositing a second metal layer on an exposed surface of the semiconductor layer of the integrated circuit.

16. The method of claim 15, including the first and second metal layer is formed of a metal selected from the group consisting essentially of nickel, cobalt, and platinum.

17. The method of claim 15 wherein the silicide proximity of the n-type field effect transistor is the distance from the second metal layer on the exposed surface of the semiconductor layer of the integrated circuit adjacent the nitride sidewall spacer and the gate of the n-type field effect transistor.

18. The method of claim 17 wherein the silicide proximity of the p-type field effect transistor is the distance from the second metal layer on the exposed surface of the semiconductor layer of the integrated circuit adjacent the nitride sidewall spacer and the gate of the p-type field effect transistor.

19. The method of claim 18 wherein the silicide proximity of the n-type field effect transistor is from about 20 nanometers to about 50 nanometers and the silicide proximity of the p-type field effect transistor is from about 45 nanometers to about 100 nanometers.

20. The method of claim 18 wherein the silicide proximity of the N-type field effect transistor is greater than the silicide proximity of the p-type field effect transistor.
